(19) United States
(12) Patent Application Publication
(10) Pub. No.: US 2011/0121319 A1
(43) Pub. Date: May 26, 2011

(54) SEMICONDUCTOR LIGHT EMITTING DEVICE AND METHOD OF MAKING SAME

(76) Inventors: Michael A. Haase, Saint Paul, MN (US); Thomas J. Miller, St. Paul, MN (US); Xiaoguang Sun, Woodbury, MN (US)

(21) Appl. No.: 12/744,553

(22) PCT Filed: Nov. 7, 2008
(86) PCT No.: PCT/US08/82778

§ 371 Date: Aug. 2, 2010

Related U.S. Application Data
(60) Provisional application No. 61/012,608, filed on Dec. 10, 2007.

(51) Int. Cl. H01L 31/153; H01L 31/0336; H01L 31/18

(52) U.S. Cl. 257/78; 438/24; 257/E31.109; 257/E31.005; 257/E31.009

(57) ABSTRACT

Light emitting devices and methods of fabricating the same are disclosed. The light emitting device includes a light emitting diode (LED) that emits blue or UV light and is attached to a semiconductor construction. The semiconductor construction includes a re-emitting semiconductor construction that includes at least one layer of a II-VI compound and converts at least a portion of the emitted blue or UV light to longer wavelength light. The semiconductor construction further includes an etch-stop construction that includes an AlInAs or a GaInAs compound. The etch-stop is capable of withstanding an etchant that is capable of etching InP.

### FIELD OF THE INVENTION

This invention generally relates to semiconductor light emitting devices. The invention is particularly applicable to semiconductor light emitting devices that include one or more II-VI compounds.

### BACKGROUND

Light emitting devices are used in many different applications, including projection display systems, backlights for liquid crystal displays and the like. Projection systems typically use one or more white light sources, such as high pressure mercury lamps. The white light beam is usually split into three primary colors, red, green and blue, and is directed to respective image forming spatial light modulators to produce an image for each primary color. The resulting primary-color image beams are combined and projected onto a projection screen for viewing.

More recently, light emitting diodes (LEDs) have been considered as an alternative to white light sources. LEDs have the potential to provide the brightness and operational lifetime that would compete with conventional light sources. Current LEDs, however, especially green emitting LEDs, are relatively inefficient.

Conventional light sources are generally bulky, inefficient in emitting one or more primary colors, difficult to integrate, and tend to result in increased size and power consumption in optical systems that employ them.

### SUMMARY OF THE INVENTION

Generally, the present invention relates to semiconductor light emitting devices.

In one embodiment, a light emitting device includes a light emitting diode (LED) that emits blue or UV light and is attached to a semiconductor construction. The semiconductor construction includes a re-emitting semiconductor construction that includes at least one layer of a II-VI compound and converts at least a portion of the emitted blue or UV light to longer wavelength light. The semiconductor construction further includes an etch-stop construction that includes an AlInAs or a GaInAs compound. The etch-stop is capable of withstanding an etchant that is capable of etching InP.

In another embodiment, a semiconductor construction includes a substrate that includes InP and is capable of being etched by a first etchant. The semiconductor construction further includes an etch-stop construction that is monolithically grown on the substrate and includes an AlInAs or a GaInAs compound. The etch-stop construction is capable of withstanding the first etchant. The semiconductor construction further includes a re-emitting semiconductor construction that is monolithically grown on the etch-stop construction and is capable of converting at least a portion of light that has a first photon energy to light that has a second photon energy smaller than the first photon energy. The re-emitting semiconductor construction includes a II-VI semiconductor potential well that has a band gap energy smaller than the first photon energy and a potential well transition energy that is substantially equal to the second photon energy. The re-emitting semiconductor construction further includes a first window construction that has a band gap energy greater than the first photon energy.

In another embodiment, a semiconductor construction includes a substrate that includes GaAs and is capable of being etched by a first etchant. The semiconductor construction further includes an etch-stop construction that is monolithically grown on the substrate and is capable of withstanding the first etchant. The semiconductor construction further includes a re-emitting semiconductor construction that is monolithically grown on the etch-stop construction and includes a II-VI potential well that has a potential well transition energy. The re-emitting semiconductor construction is capable of converting at least a portion of light that has a first photon energy to light that has a second photon energy smaller than the first photon energy.

In another embodiment, a semiconductor construction includes a substrate that includes Ge and is capable of being etched by a first etchant. The semiconductor construction further includes an etch-stop construction that is monolithically grown on the substrate and includes (Al)GaInAs, (Al)GaAs, AlInP, GaInP, or Al(Ga)AsP. The etch-stop construction is capable of withstanding the first etchant. The semiconductor construction further includes a re-emitting semiconductor construction that is monolithically grown on the etch-stop construction and is capable of converting at least a portion of light that has a first photon energy to light that has a second photon energy smaller than the first photon energy. The re-emitting semiconductor construction includes a II-VI semiconductor potential well that has a band gap energy that is smaller than the first photon energy and a potential well transition energy that is substantially equal to the second photon energy. The re-emitting semiconductor construction further includes an absorbing layer that is closely adjacent to the potential well and has a band gap energy that is greater than the potential well transition energy and smaller than the first photon energy.

In another embodiment, a semiconductor construction includes a semiconductor substrate that is capable of withstanding a first etchant. The semiconductor construction further includes a semiconductor sacrificial layer that is monolithically grown on the substrate and is capable of being etched by the first etchant. The semiconductor construction further includes a re-emitting semiconductor construction that is monolithically grown on the sacrificial layer and is capable of converting at least a portion of light that has a first photon energy to light that has a second photon energy smaller than the first photon energy. The re-emitting semiconductor construction includes a II-VI semiconductor potential well that has a band gap energy smaller than the first photon energy and a potential well transition energy that is substantially equal to the second photon energy. The re-emitting semiconductor construction further includes an absorbing layer that is closely adjacent to the potential well and has a band gap energy that is greater than the potential well transition energy and smaller than the first photon energy. At least some layers in the re-emitting semiconductor construction can withstand the first etchant.

In another embodiment, a semiconductor system includes a plurality of discrete light sources that are monolithically integrated onto a first substrate. The semiconductor system further includes a semiconductor construction that includes a second substrate that is capable of being etched by a first etchant. The semiconductor construction further includes an etch-stop construction that is monolithically grown on the second substrate and is capable of withstanding the first etchant. The semiconductor construction further includes a re-emitting semiconductor construction that is monolithically grown on the etch-stop construction and is capable of converting at least a portion of light emitted by each of the plurality of discrete light source to a longer wavelength light. The re-emitting semiconductor construction is attached to and covers the plurality of discrete light sources.

In another embodiment, a method of fabricating a semiconductor construction, includes the steps of: (a) providing a substrate; (b) monolithically growing an etch-stop layer on the substrate; (c) monolithically growing a potential well on the etch-stop layer; (d) bonding the potential well to a light source; (e) removing the substrate by a first etchant that is that the etch-stop layer can withstand; and (f) removing the etch-stop layer by a second etchant.

### BRIEF DESCRIPTION OF DRAWINGS

The invention may be more completely understood and appreciated in consideration of the following detailed description of various embodiments of the invention in connection with the accompanying drawings, in which:

FIG. 1 is a schematic side-view of a light emitting device;

FIGS. 2A-2F are schematic representations of exemplary conduction band profiles for a potential well;

FIG. 3 is a schematic side-view of a light emitting device;

FIG. 4 is a schematic side-view of a portion of the light emitting device of FIG. 3; and

FIGS. 5A-5E are schematic representations of devices at intermediate stages or steps in a process for fabricating a light emitting device.

The same reference numeral used in multiple figures refers to the same or similar elements having the same or similar properties and functionalities.

### DETAILED DESCRIPTION

This application discloses methods for fabricating semiconductor light emitting devices that include a semiconductor light source and a semiconductor wavelength converter. In particular, the disclosed methods allow for efficient, compact, and inexpensive integration of a wavelength converter with a light source from two or more different semiconductor groups. For example, this application teaches methods for integrating a semiconductor wavelength converter with a semiconductor light source where it is not possible or practical to monolithically grow one onto the other with high quality using conventional semiconductor processing methods.

In some cases, semiconductor wavelength converters and light sources are from the same semiconductor group, such as the III-V group. In such cases, it may be feasible to monolithically grow and fabricate, for example, a III-V wavelength converter directly onto a III-V light source, such as a III-V LED. In some cases, however, a wavelength converter that has high conversion efficiency and/or other desirable properties, is from a semiconductor group that is different than the group the LED belongs to. In such cases, it may not be possible or feasible to grow one component onto the other with high quality. For example, a wavelength converter can be from the II-VI group and a light source, such as an LED, can be from the III-V group. In such cases, this application discloses methods for fabricating a light emitting device by efficiently integrating a wavelength converter with a light source by first fabricating the wavelength converter on a suitable substrate and then attaching the wavelength converter to the light source. The substrate can be removed before or after the attachment. The disclosed methods allow for the removal of the substrate without affecting the performance and/or properties of the wavelength converter or the light emitting device.

In some cases, the wavelength converter can include a potential or quantum well, such as a semiconductor potential or quantum well, that can convert light to a longer wavelength light. The disclosed methods can be employed effectively to fabricate semiconductor constructions and light emitting devices that include one or more potential or quantum wells from a semiconductor group, such as the II-VI group, integrated with light sources, such as LEDs, from a different semiconductor group, such as the III-V group. The disclosed fabrication methods allow for reduced fabrication cost by, for example, using components, such as substrates, that are inexpensive, easy to obtain, and easy to process, for example easy to remove from an epitaxial stack of layers.

In some cases, a light source, such as an LED, can belong to a semiconductor group and operate in an efficient region of the spectrum, meaning that the light source is capable of emitting light efficiently and at high intensities. In such cases, there may not be a suitable, such as an efficient, wavelength converter that belongs to the same semiconductor group. For example, the light source can be a III-V LED and the suitable wavelength converter can be a II-VI potential or quantum well capable of down converting light emitted by the LED to longer wavelength light with high efficiency and with desirable properties such as high intensity and small dispersion. The wavelength converter can be integrated with the LED using the disclosed methods resulting in compact, light weight, and inexpensive light emitting devices. Such light emitting devices can emit light with high overall efficiency at different wavelengths, for example, in the visible region of the spectrum. The light emitting devices can be designed to output, for example, one or more primary colors or white light. The emission efficiency and compactness of the disclosed light emitting devices can lead to new and improved optical systems, such as portable projection systems, with reduced weight, size, and power consumption.

In some cases, the disclosed methods can be utilized to fabricate a wavelength converter, such as a potential well wavelength converter, on a suitable substrate, such as a substrate on which the wavelength converter can be grown pseudomorphic or lattice matched. In some cases, it is desirable to remove the substrate. For example, the substrate may be optically opaque and/or undesirably thick. In such cases, the substrate may be etched until the entire substrate is removed, but because of the large thickness of the substrate, it is difficult to avoid etching the wavelength converter. Furthermore, the resulting etched surface can be unacceptably rough affecting, for example, the performance of the wavelength converter.

The methods disclosed in this application allow for the removal of the substrate with no or little adverse affect on the wavelength converter and/or the light emitting device. In some cases, one or more thin etch-stop layers can be disposed between the wavelength converter and the substrate so that the substrate can be removed by, for example, using an etchant that does not etch or only slightly etches the etch-stop layer. In such cases, the etch-stop layer can effectively protect the wavelength converter from the etchant. In some cases, the etch-stop layer may be retained in the light emitting device. In some other cases, the thin etch-stop layer can be removed by, for example, using an etchant without affecting the wavelength converter.

In some cases, one or more sacrificial layers can be disposed between the wavelength converter and the substrate. In such cases, the sacrificial layer is capable of being etched by an etchant that can be withstood by the wavelength converter and, in some cases, also by the substrate. As such, the substrate can be removed, by etching the sacrificial layer without adversely affecting the properties of the wavelength converter.

The disclosed methods can be employed to fabricate integrated array of light sources to form monochromatic (for example, green or green and black) or color images. Such disclosed array of light emitted devices can combine the primary functions of light sources and image forming devices resulting in reduced power consumption, size, and cost. For example, in a display system, the disclosed light emitting devices can function as both the light source and the image forming device, thereby eliminating or reducing the need for a backlight or a spatial light modulator. As another example, incorporating the disclosed light emitting devices in a projection system eliminates or reduces the need for image forming devices and relay optics.

Arrays of luminescent elements, such as arrays of pixels in a display system, are disclosed in which at least some of the luminescent elements include an electroluminescent device, such as an LED, capable of emitting light in response to an electric signal. At least some of the luminescent elements can include one or more light converting elements, such as one or potential wells and/or quantum wells, for down converting light that is emitted by the electroluminescent devices. As used herein, down converting means that the wavelength of the converted light is greater than the wavelength of the unconverted or incident light.

Arrays of luminescent elements disclosed in this application can be used in illumination systems, such as adaptive illumination systems, for use in, for example, projection systems or other optical systems.

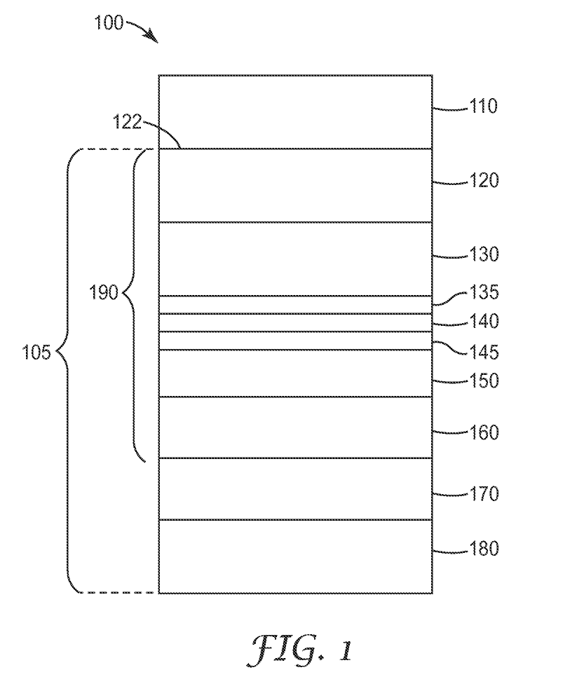

FIG. 1 is a schematic side-view of a light emitting device 100 that includes a light source 110 attached to a semiconductor construction 105. Semiconductor construction 105 includes a substrate 180, an etch-stop construction 170 monolithically grown on substrate 180, and a monolithic re-emitting semiconductor construction 190 monolithically grown on etch-stop construction 170. Re-emitting semiconductor construction absorbs at least a portion of light emitted by light source 110 and re-emits at least a portion of the absorbed light as a longer wavelength light. For example, light source 110 can emit UV light and the re-emitting semiconductor construction can re-emit blue, green, or red light. As another example, light source 110 can emit blue light and the re-emitting semiconductor construction can re-emit green or red light.

As used herein, monolithic integration includes, but is not necessarily limited to, two or more electronic devices that are manufactured on the same substrate (a common substrate) and used in an end application on that same substrate. Monolithically integrated devices that are transferred to another substrate as a unit remain monolithically integrated. Exemplary electronic devices include LEDs, transistors, and capacitors.

Where portions of each of two or more elements are monolithically integrated, the two elements are considered to be monolithically integrated. For example, two light emitting devices are monolithically integrated if, for example, the light sources in the two elements are monolithically integrated. This is so, even if, for example, a light converting component in each element is adhesively bonded to the corresponding light source.

In cases where an array of light emitting devices include semiconductor layers, the array of light emitting devices are monolithically integrated if the devices are manufactured on the same substrate and/or if they include a common semiconductor layer. For example, where each light emitting device includes an n-type semiconductor layer, the light emitting devices are monolithically integrated if the n-type semiconductor layer extends across the light emitting devices. In such a case, the n-type semiconductor layers in the light emitting devices form a continuous layer across the array of light emitting devices.

In some cases, such as when substrate 180 and/or etch-stop construction 170 are optically opaque and/or unacceptably thick, the substrate and/or the etch-stop construction can be removed from light emitting device.

In general, light source 110 can be any light source capable of emitting light at a desired wavelength or in a desired wavelength range. For example, in some cases, light source 110 can be an LED emitting blue or UV light. In some cases, light source 110 can be a III-V semiconductor light source, such as a III-V LED, and may include AlGaInN semiconductor alloys. For example, light source 110 can be a GaN based LED.

In some cases, light source 110 can include one or more p-type and/or n-type semiconductor layers, one or more active layers that may include one or more potential and/or quantum wells, buffer layers, substrate layers, and superstrate layers.

Light source 110 can be attached or bonded to semiconductor construction 105 by any suitable method such as by an adhesive such as a hot melt adhesive, welding, pressure, heat or any combinations of such methods or other methods that may be desirable in an application. Examples of suitable hot melt adhesives include semicrystalline polyolefins, thermoplastic polyesters, and acrylic resins.

Other exemplary bonding materials include optically clear polymeric materials, such as optically clear polymeric adhesives, including acrylate-based optical adhesives, such as Norland 83H (supplied by Norland Products, Cranbury N.J.); cyanoacrylates such as Scotch-Weld instant adhesive (supplied by 3M Company, St. Paul, Minn.); benzocyclobutenes such as Cyclotene™ (supplied by Dow Chemical Company, Midland, Mich.); clear waxes such as CrystalBond (Ted Pella Inc., Redding Calif.); liquid, water, or soluble glasses based on Sodium Silicate; and spin-on glasses (SOG).

In some cases, light source 110 can be attached to semiconductor construction 105 by a wafer bonding technique. For example, in reference to FIG. 1, the lowermost surface of light source 110 and the uppermost surface of semiconductor construction 105 can be coated with a thin layer of silica or other inorganic materials using, for example, a plasma assisted or conventional CVD process. Next, the coated surfaces can be optionally planarized and bonded to each other using a combination of heat, pressure, water, or one or more chemical agents. The bonding can be improved by bombarding at least one of the coated surfaces with hydrogen atoms or by activating one or both surfaces with low energy plasma. Wafer bonding methods are described in, for example, U.S. Pat. Nos. 5,915,193 and 6,563,133, and in chapters 4 and 10 of “Semiconductor Wafer Bonding” by Q.-Y. Tong and U. Gösele (John Wiley & Sons, New York, 1999).

Re-emitting semiconductor construction 190 includes first and second windows 120 and 160, respectively, first and second absorbing layers 130 and 150, respectively and potential well 140. Re-emitting semiconductor construction 190 includes at least one layer of a II-VI compound that is capable of converting at least a portion of a light, such as a blue or UV light to a longer wavelength light. In some cases, the II-VI wavelength converter includes a II-VI potential or quantum well.

As used herein, potential well means semiconductor layer(s) in a multilayer semiconductor structure designed to confine a carrier in one dimension only, where the semiconductor layer(s) has a lower conduction band energy than the surrounding layers and/or a higher valence band energy than the surrounding layers. Quantum well generally means a potential well which is sufficiently thin that quantization effects increase the energy for electron-hole pair recombination in the well. A quantum well typically has a thickness of about 100 nm or less, or about 10 nm or less.

In some cases, a potential or quantum well 140 includes a II-VI semiconductor potential or quantum well that has a band gap energy that is smaller than the energy of a photon emitted by light source 110. In general, the potential well transition energy of a potential or quantum well 140 is substantially equal to the energy of a photon that is re-emitted by the potential or quantum well.

In some cases, potential well 140 can include CdMgZnSe alloys having compounds ZnSe, CdSe, and MgSe as the three constituents of the alloy. In some cases, one or more of Cd, Mg, and Zn, especially Mg, may be absent from the alloy. For example, potential well 140 can include a Cd_{0.70}Zn_{0.30}Se quantum well capable of re-emitting in the red, or a Cd_{0.33}Zn_{0.67}Se quantum well capable of re-emitting in the green. As another example, potential well 140 can include an alloy of Cd, Zn, Se, and optionally Mg, in which case, the alloy system can be represented by Cd(Mg)ZnSe. As another example, potential well 140 can include an alloy of Cd, Mg, Se, and optionally Zn. In some cases, the potential well can include ZnSeTe. In some cases, a quantum well 140 has a thickness in a range from about 1 nm to about 100 nm, or from about 2 nm to about 35 nm.

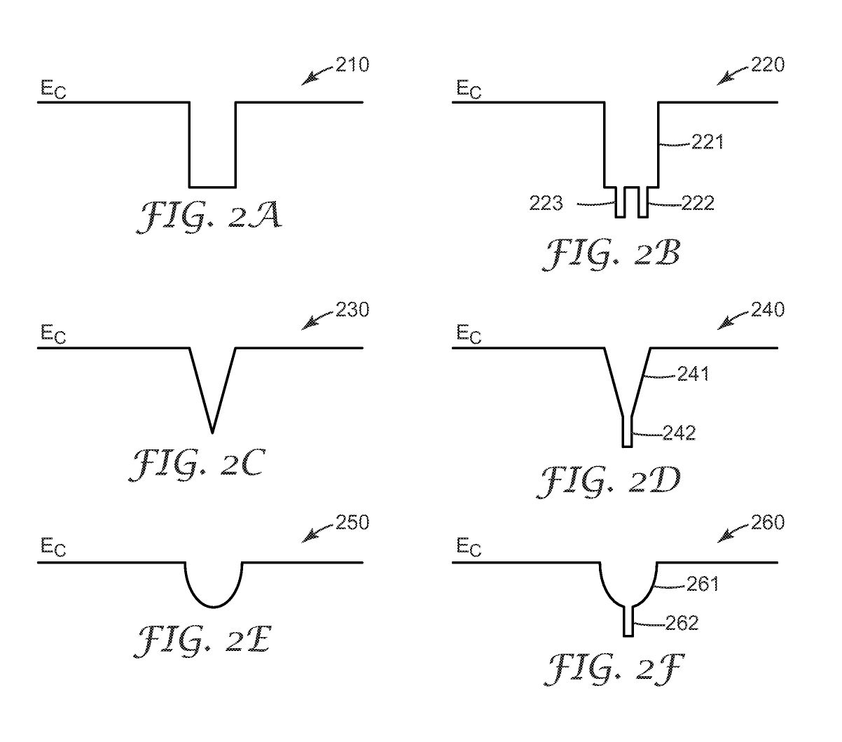

In some cases, potential well 140 is capable of converting at least a portion of light that is emitted by light source 110 to a longer wavelength light. In some cases, potential well 140 can include a II-VI potential well. In general, potential well 140 can have any conduction and/or valence band profile. Some exemplary conduction band profiles for a potential well are shown schematically in FIGS. 2A-2F where E_{C} denotes the conduction band energy. In particular, a potential well 210 shown in FIG. 2A has a square or rectangular profile; a potential well 220 shown in FIG. 2B has a first rectangular profile 221 combined with a second rectangular profile 222 and a third rectangular profile 223; a potential well 230 shown in FIG. 2C has a linearly graded profile; a potential well 240 shown in FIG. 2D has a linearly graded profile 241 combined with a rectangular profile 242; a potential well 250 shown in FIG. 2E has a curved, such as a parabolic, profile; and a potential well 260 shown in FIG. 2F has a parabolic profile 261 combined with a rectangular profile 262.

In some cases, potential well 140 can be n-doped or p-doped where the doping can be accomplished by any suitable method and by inclusion of any suitable dopant. In some cases, light source 110 and re-emitting semiconductor construction 190 can be from two different semiconductor groups. For example, in some cases, light source 110 can be a III-V semiconductor device and re-emitting semiconductor construction 190 can be a II-VI semiconductor device. In some cases, light source 110 can include AlGaInN semiconductor alloys and re-emitting semiconductor construction 190 can include Cd(Mg)ZnSe semiconductor alloys.

In some cases, light emitting device 100 can have a single potential well. In some cases, light emitting device 100 can have at least 2 potential wells, or at least 5 potential wells, or at least 10 potential wells.

First and second absorbing layers 130 and 150 are proximate potential well 140 to assist in absorbing light emitted from LED 110. In some cases, the absorbing layers include materials such that a photogenerated carrier in the materials can efficiently diffuse to the potential well. In some cases, the light absorbing layers can include a semiconductor, such as an inorganic semiconductor, such as a II-VI semiconductor. For example, at least one of absorbing layers 130 and 150 can include a Cd(Mg)ZnSe semiconductor alloy.

In some cases, a light absorbing layer has a band gap energy that is smaller than the energy of a photon emitted by light source 110. In such cases, the light absorbing layer can strongly absorb light that is emitted by the light source. In some cases, a light absorbing layer has a band gap energy that is greater than the transition energy of potential well 140. In such cases, the light absorbing layer is substantially optically transparent to light that is re-emitted by the potential well.

In some cases, at least one of light absorbing layers 130 and 150 can be closely adjacent to potential well 140, meaning that one or a few intervening layers may be disposed between the absorbing layer and the potential well. In some cases, at least one of light absorbing layers 130 and 150 can be immediately adjacent to potential well 140, meaning that no intervening layer is disposed between the absorbing layer and the potential well.

The exemplary light emitting device 100 includes two light absorbing layers 130 and 150. In general, a light emitting device can have no, one, two, or more than two absorbing layers. In general, a light absorbing layer is sufficiently close to potential well 140 so that a photo-generated carrier in the light absorbing layer has a reasonable chance of diffusing to the potential well.

First and second windows 120 and 160 are designed primarily to provide barriers so that carriers, such as electron-hole pairs, that are photo-generated in an absorbing layer do not, or have a small chance to, migrate to a free or external surface, such as surface 122, of re-emitting semiconductor construction 190. For example, first window 120 is designed primarily to prevent carriers generated in first absorbing layer 130 by light emitted by light source 110, from migrating to surface 122 where they can recombine non-radiatively. In some cases, windows 120 and 160 have band gap energies that are greater than the energy of a photon emitted by light source 110. In such cases, windows 120 and 160 are substantially optically transparent to light emitted by light source 110 and light re-emitted by potential well 140.

Exemplary light emitting device 100 includes two windows. In general, a light emitting device can have no or any number of windows. For example, in some cases, light emitting device 100 has a single window disposed between light source 110 and potential well 140, or between light source 110 and absorbing layer 130.

In some cases, the location of an interface between two adjacent layers in light emitting device 100 may be a well-defined or sharp interface. In some cases, such as when the material composition within a layer changes as a function of distance along the thickness direction, the interface between two adjacent layers may not be well defined and may, for example, be a graded interface. For example, in some cases, first absorbing layer 130 and first window 120 can have the same material components but with different material concentrations. In such cases, the material composition of the absorbing layer may be gradually changed to the material composition of the window layer resulting in a graded interface between the two layers. For example, in cases where both layers include Mg, the concentration of Mg can be increased when gradually transitioning from the absorbing layer to the window.

Etch-stop construction 170 is disposed between re-emitting semiconductor construction and substrate 180 and is designed primarily to withstand an etchant that is capable of etching substrate 180. An etch-stop construction withstands an etchant that is capable of etching a substrate if, for example, at least a portion of the etch-stop construction remains un-etched by the etchant after the etchant etches substantially the entire substrate. In some cases, the etch rate of the substrate is at least 10 times greater than the etch rate of the etch-stop construction, or at least 20 times greater than the etch rate of the etch-stop construction, or at least 50 times greater than the etch rate of the etch-stop construction, or at least 100 times greater than the etch rate of the etch-stop construction.

In some cases, etch-stop layer 170 is substantially thinner than substrate 180. For example, in some cases, the thickness of etch-stop construction 170 is less than about 10 microns, or less than about 8 microns, or less than about 5 microns, or less than about 2 microns, or less than about 1 micron; and the thickness of substrate 180 is greater than about 50 microns, or greater than about 100 microns, or greater than about 200 microns, or greater than about 300 microns, or greater than about 500 microns, or greater than about 1000 microns.

In some cases, etch-stop 170 is or includes a layer that is grown pseudomorphic on substrate 180, meaning that the lattice constant of a crystalline etch-stop construction 170 is sufficiently similar to the lattice constant of a crystalline substrate 180 so that when fabricating or growing the etch-stop on the substrate, the etch-stop can adopt the lattice spacing of the substrate with no or with low density misfit defects. In such cases, the lattice constant of the etch-stop construction can be constrained to the lattice constant of the substrate.

In some cases, etch-stop 170 is or includes a layer that is lattice matched to substrate 180, meaning that the lattice constant of a crystalline etch-stop construction 170 is substantially equal to the lattice constant of a crystalline substrate 180 where by substantially equal it is meant that the two lattice constants are not more than about 0.2% different from each other, or not more than about 0.1% different from each other, or not more than about 0.01% different from each other.

In some cases, substrate 180 can include InP. In such cases, etch-stop construction 170 can include one or more AlGaInAs alloys such as GaInAs and/or AlInAs, and/or one or more GaInAsP alloys. An InP substrate can be removed by etching the substrate in, for example, an HCl solution at room or an elevated temperature. In such cases, an AlGaInAs or a GaInAsP etch-stop construction 170 can effectively withstand the HCl solution. A GaInAs etch-stop construction 170 can be removed by, for example, using an etching solution that includes about 30 ml of a 30% ammonium hydroxide, 5 ml of a 30% hydrogen peroxide, 40 grams of adipic acid, and 200 ml of water. As an example, such a solution, when agitated, can etch a 200 nm thick GaInAs in about 5 minutes. In some cases, a GaInAs etch-stop construction 170 can be removed by subjecting the construction to a plasma, an ion-beam, or other wet etchants.

In some cases, substrate 180 can include Ge. In such cases, etch-stop construction 170 can include an AlGaInAs alloy such as GaInAs and/or AlInAs; GaInP; AlGaInP; Al(Ga)AsP; or an (Al)GaAs alloy such as GaAs and/or AlGaAs. An advantage of a Ge substrate is that the substrate is non-toxic and is typically less expensive than, for example, a GaAs substrate. A Ge substrate can be removed by etching the substrate with, for example, CF4/O2 plasma as described in, for example, R. Venkatasubramanian, et al., “Selective Plasma Etching of Ge Substrates for Thin Freestanding GaAs—AlGaAs Heterostructures,” Appl. Phys. Lett. Vol. 59, p. 2153 (1991).

In some cases, substrate 180 can include GaAs. In such cases, etch-stop construction 170 can be monolithically grown on the GaAs substrate and can withstand and etchant that is capable of etching GaAs. For example, etch-stop construction 170 can include a II-VI compound such as BeTe, an AlGaAs alloy, or an AlGaInP alloy such as GaInP or AlInP.

In some cases, such as when the etch-stop layer includes AlGaAs, a GaAs substrate can be removed by etching the substrate in, for example, a solution of NH₄OH and sufficiently concentrated H₂O₂ at room or an elevated temperature and, for example, with aggressive agitation. In such cases, the etching can substantially stop at the AlGaAs etch-stop construction due to, for example, a formation of aluminum oxide on the etch-stop surface.

In some cases, such as when the etch-stop layer includes GaInP, a GaAs substrate can be removed by etching the substrate in, for example, an aqueous solution of H₂SO₄ and H₂O₂. In such cases, the etching can substantially stop at the GaInP etch-stop construction.

In some cases, such as when a thin etch-stop construction includes an AlGaAs alloy, an AlGaInP alloy such as GaInP or AlInP, or BeTe, the etch-stop layer can be removed by using any appropriate etching technique, such as a plasma etching method or an ion-beam etching method, and monitoring, for example, the etching time so that the etching can be terminated when substantially the entire etch-stop is removed.

In some cases, such as when substrate 180 includes GaAs, an absorbing layer, such as first absorbing layer 130, and/or a window, such as first window 120, can include, for example, a MgZnSSe alloy and/or a BeMgZnSe alloy.

In some cases, such as when substrate 180 includes GaAs, potential well 140 can include, for example, compressively-strained alloys of CdZn(S)Se and/or ZnSeTe where a material enclosed in parentheses is an optional material. In such cases, light emitting device can have additional layers, such as first and second strain-compensation layers 135 and 145, respectively, for compensating or alleviating strain in potential well 140. A strain-compensation layer can include, for example, ZnSSe and/or BeZnSe. The exemplary light emitting device 100 includes two strain-compensation layers, one on each side of potential well 140. In general, the light emitting device can have no, one, or two or more strain-compensation layers. For example, in some cases, the light emitting device can have a single strain-compensation layer on only one side of potential well 140.

In some cases, substrate 180 and etch-stop construction 170 are removed from light emitting device 100. In some cases, these two components are removed after semiconductor construction 105 is attached to light source 110. In some cases, these two components are removed before semiconductor construction 105 is attached to light source 110.

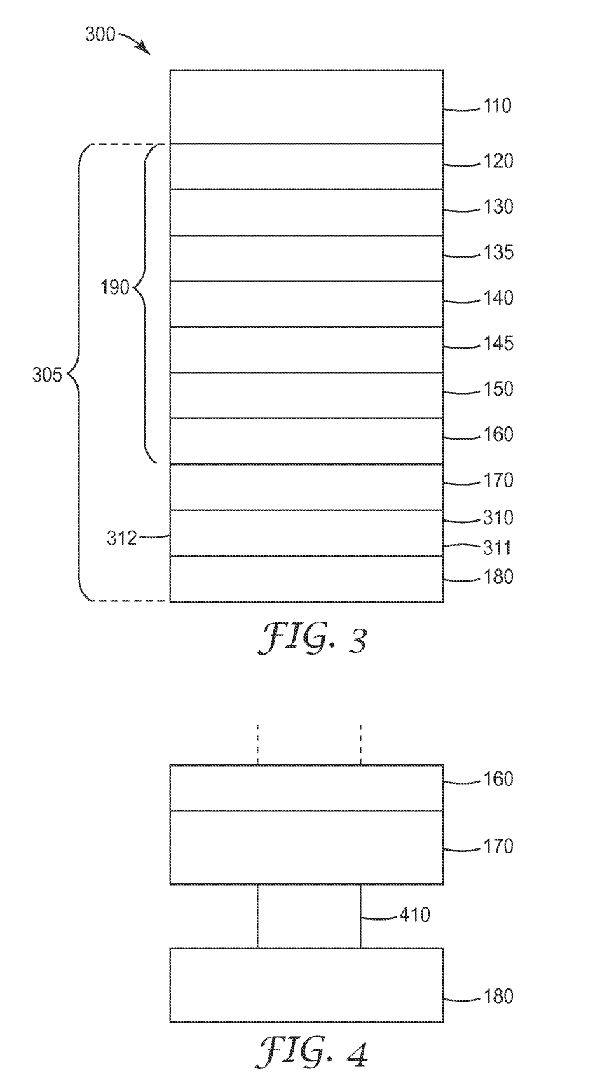

FIG. 3 is a schematic side-view of a light emitting device 300 that includes light source 110 attached to a semiconductor construction 305. Semiconductor construction 305 includes substrate 180, a sacrificial layer 310 monolithically grown on substrate 180, etch-stop construction 170 monolithically grown on sacrificial layer 310, and monolithic re-emitting semiconductor construction 190 monolithically grown on etch-stop construction 170. Re-emitting semiconductor construction absorbs at least a portion of light emitted by light source 110 and re-emits at least a portion of the absorbed light as longer wavelength light.

In some cases, substrate 180 can be removed from semiconductor construction 305 by removing sacrificial layer 310 by, for example, accessing and etching the sacrificial layer from sides 311 and 312. In some cases, such as when sacrificial layer 310 can be removed without adversely affecting re-emitting semiconductor construction 190, etch-stop construction 170 can be absent from light emitting device 300.

In some cases, substrate 180 can include Ge or GaAs, and sacrificial layer 310 can include a pseudomorphic AlAs or MgSe, or a lattice-matched MgZnSe grown on the substrate. For example, an AlAs sacrificial layer can be removed by at least partially immersing the light emitting device in an HF solution as described in, for example, E. Yablonovitch, et al., “Van der Waals Bonding of GaAs Epitaxial Liftoff Films onto Arbitrary Substrates,” Appl. Phys. Lett. Vol. 56, p. 2419 (1990). As another example, a MgSe sacrificial layer can be removed by at least partially immersing the light emitting device in an HF solution. FIG. 4 is a schematic side-view of a portion of light emitting device 300, where layer 410 is a partially etched sacrificial layer 310.

In some cases, such as when sacrificial layer 310 is substantially thinner than substrate 180, removing the substrate by etching the sacrificial layer can be more desirable, for example because it is less time consuming and/or less expensive, than etching the substrate. In some cases, the removed substrate can be discarded. In some cases, the removed substrate can be reused after, for example, reconditioning, such as cleaning and/or polishing. In some cases, the thickness of sacrificial layer 310 is less than about 10 microns, or less than about 8 microns, or less than about 5 microns, or less than about 2 microns, or less than about 1 micron, or less than about 0.5 microns, or less than about 0.2 microns; and the thickness of substrate 180 is greater than about 50 microns, or greater than about 100 microns, or greater than about 200 microns, or greater than about 300 microns, or greater than about 500 microns, or greater than about 1000 microns.

In some cases, at least some of the layers and components in re-emitting semiconductor construction 190, such as a window layer, a potential well layer, and/or an absorbing layer, can withstand an etchant that is capable of etching sacrificial layer 310. In some cases, the entire re-emitting semiconductor construction can withstand an etchant that is capable of etching sacrificial layer 310.

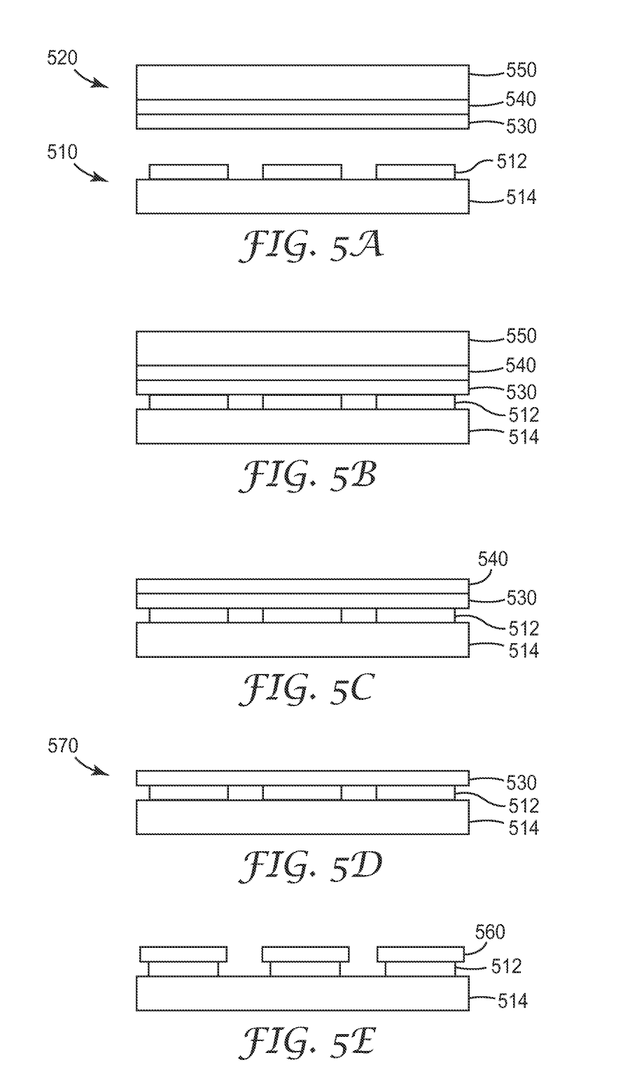

FIG. 5A is a schematic side-view of a semiconductor construction 520 and a light source assembly 510. In some cases, semiconductor construction 520 can be similar to any embodiments disclosed herein, such as semiconductor construction 105, and can include a substrate 550 similar to substrate 180, an etch-stop construction 540 similar to etch-stop construction 170 monolithically grown on substrate 550, and a re-emitting semiconductor construction similar to re-emitting semiconductor construction 190 monolithically grown on etch-stop construction 170.

Light source assembly 510 includes a plurality of discrete light sources 512 monolithically fabricated on a common substrate 514. In some cases, a discrete light source 512 can be similar to light source 110. For example, a discrete light source 512 can be a III-VI LED.

Each of semiconductor construction 520 and light source assembly 510 can be fabricated using known fabrication methods, such as epitaxial deposition methods. For example, a molecular-beam epitaxy (MBE) process may be used to deposit layers 530 and 540 on a substrate 550, such as, for example, an InP substrate 550. Other exemplary manufacturing methods include chemical vapor deposition (CVD), metal-organic vapor phase deposition (MOCVD), liquid phase epitaxy (LPE), and vapor phase epitaxy (VPE).

In some cases, such as when discrete light sources 512 include LEDs, the discrete light sources can be constructed using known fabrication methods such as MOCVD where substrate 514 can be, for example, a sapphire substrate, a SiC substrate, a GaN substrate, or any other substrate that may be suitable in an application. In some cases, LED light sources 512 can include such layers and/or components as electrodes, transparent electrical contacts, vias, and bonding layers. In general, light sources 512 can be fabricated using conventional methods used in the semiconductor micro-fabrication industry, such as conventional photolithography methods and conventional etching and/or deposition methods.

FIG. 5B is a schematic side-view of the two construction from FIG. 5A attached or bonded to each other with re-emitting semiconductor construction facing light sources 512. The attachment may be carried out by, for example, direct wafer bonding or by disposing one or more bonding layers between the two wafers during the bonding process. A bonding layer can, for example, include one or more thin or very thin metal layers, one or more thin metal oxide layers, or one or more layers of other materials such as adhesives, encapsulants, high index glasses, or sol-gel materials such as low temperature sol-gel materials, or any combinations thereof.

In some cases, the thickness of a bonding layer used in attaching light source assembly 510 to semiconductor construction 520 can be in a range from about 5 nm to about 200 nm, or from about 10 nm to about 100 nm, or from about 50 nm to about 100 nm. In some cases, such as when a bonding layer is an optical adhesive, the thickness of the bonding layer may be greater that about 1 μm, or greater than about 2 μms, or greater than about 5 μms, or greater than about 7 μms, or greater than about 10 μm. In some cases, the bonding between the two components may be accomplished by, for example, lamination or an application of temperature and/or pressure.

After light source assembly 510 is bonded to semiconductor construction 520, substrate 550 is removed using a method disclosed herein resulting in the structure shown schematically in FIG. 5C.

In some cases, etch-stop construction may also be removed, for example, using one or a combination of the methods disclosed in this application resulting in an array of light emitting devices 570 shown schematically in FIG. 5D. Array of light emitting devices 570 includes a re-emitting semiconductor construction 530 that extends across an array or a plurality of discrete light emitting sources 512. In some cases, at least some portions of re-emitting semiconductor construction 530 between adjacent discrete light emitting sources 512 can be removed resulting in the construction showed schematically in FIG. 5E where re-emitting semiconductor construction 560 is a portion of re-emitting semiconductor construction 530.

The removal of portions of re-emitting semiconductor construction 530 can be accomplished by, for example, using known patterning and etching methods. Exemplary patterning methods include photolithography. Exemplary etching methods include wet etching. For example, a II-VI semiconductor light converting element can be etched using a solution that contains methanol and bromine.

In some cases, the emitting devices in array of light emitting devices 570 are configured as an active matrix, meaning that each emitting device includes a dedicated switching circuit for driving the emitting device in the array light emitting devices.

In some cases, the emitting devices in array of light emitting devices 570 are configured as a passive matrix, meaning that the emitting devices are not configured as an active matrix. In a passive matrix configuration, no emitting device has a dedicated switching circuit for driving the device in the array of light emitting devices.

Typically, in a passive matrix configuration, the light emitting devices in the array of light emitting devices are energized one row at a time. In contrast, in an active matrix configuration, although the rows are typically addressed one at a time, the switching circuits typically allow the light emitting devices to be energized continuously.

As used herein, terms such as “vertical”, “horizontal”, “above”, “below”, “left”, “right”, “upper” and “lower”, “top” and “bottom” and other similar terms, refer to relative positions as shown in the figures. In general, a physical embodiment can have a different orientation, and in that case, the terms are intended to refer to relative positions modified to the actual orientation of the device. For example, even if the construction in FIG. 3 is rotated 90 degrees as compared to the orientation in the figure, surface 312 is still considered to be a “side” of sacrificial layer 310.

While specific examples of the invention are described in detail above to facilitate explanation of various aspects of the invention, it should be understood that the intention is not to limit the invention to the specifics of the examples. Rather, the intention is to cover all modifications, embodiments, and alternatives falling within the spirit and scope of the invention as defined by the appended claims.

What is claimed is:

1. A light emitting device comprising a light emitting diode (LED) emitting blue or UV light attached to a semiconductor construction comprising:
a re-emitting semiconductor construction comprising at least one layer of a II-VI compound converting at least a portion of the emitted blue or UV light to a longer wavelength light; and
an etch-stop construction comprising an AlInAs or a GaInAs compound, the etch-stop being capable of withstanding an etchant that is capable of etching InP.

2. The light emitting device of claim 1, wherein the LED comprises a GaN based LED.

3. The light emitting device of claim 1, wherein the at least one layer of a II-VI compound comprises a potential well.

4. The light emitting device of claim 3, wherein the potential well comprises Cd(Mg)ZnSe or ZnSeTe.

5. The light emitting device of claim 3, wherein the re-emitting semiconductor construction further comprises an absorbing layer closely adjacent to and having a band gap energy greater than a transition energy of the potential well.

6. The light emitting device of claim 5, wherein the absorbing layer is immediately adjacent to the potential well.

7. The light emitting device of claim 1, wherein the longer wavelength light comprises a green light.

8. The light emitting device of claim 1, wherein the longer wavelength light comprises a red light.

9. The light emitting device of claim 1, wherein the AlInAs or GaInAs compound can be grown pseudomorphic on InP.

10. The light emitting device of claim 1, wherein the AlInAs or GaInAs compound is lattice matched to InP.

11. The light emitting device of claim 1, wherein the AlInAs or GaInAs compound comprises a AlGaInAs compound.

12. The light emitting device of claim 1, wherein the AlInAs or GaInAs compound comprises an GaInAsP compound.

13. The light emitting device of claim 1, wherein the AlInAs or GaInAs compound comprises a AlGaInAsP compound.

14. A semiconductor construction comprising:
a substrate comprising InP capable of being etched by a first etchant;
an etch-stop construction monolithically grown on the substrate and comprising an AlInAs or a GaInAs compound, the etch-stop construction being capable of withstanding the first etchant;
a re-emitting semiconductor construction monolithically grown on the etch-stop construction and capable of converting at least a portion of light having a first photon energy to light having a second photon energy smaller than the first photon energy, the re-emitting semiconductor construction comprising:
a II-VI semiconductor potential well having a band gap energy smaller than the first photon energy and a potential well transition energy substantially equal to the second photon energy; and
a first window construction having a band gap energy greater than the first photon energy.

15. The semiconductor construction of claim 14, wherein the re-emitting semiconductor construction further comprises an absorbing layer closely adjacent to the potential well and having a band gap energy greater than the potential well transition energy and smaller than the first photon energy.

16. The semiconductor construction of claim 15 further comprising a light emitting diode (LED) emitting light having the first photon energy, the LED being attached to the re-emitting semiconductor construction, the window being disposed between the absorbing layer and the LED.

17. The semiconductor construction of claim 14, wherein the first photon energy corresponds to a blue or UV light.

18. The semiconductor construction of claim 14, wherein the potential well comprises Cd(Mg)ZnSe or ZnSeTe.

19. A semiconductor construction comprising:
a substrate comprising GaAs capable of being etched by a first etchant;
an etch-stop construction monolithically grown on the substrate capable of withstanding the first etchant;
a re-emitting semiconductor construction monolithically grown on the etch-stop construction and comprising a II-VI potential well having a potential well transition energy, the re-emitting semiconductor construction being capable of converting at least a portion of light having a first photon energy to light having a second photon energy smaller than the first photon energy.

20. The semiconductor construction of claim 19, wherein the etch-stop is grown pseudomorphic on GaAs.

21. The semiconductor construction of claim 19, wherein the etch-stop is lattice matched to GaAs.

22. The semiconductor construction of claim 19, wherein the etch-stop comprises at least one of a II-VI compound, AlGaAs, GaInP, and BeTe.

23. The semiconductor construction of claim 19 wherein the II-VI potential well comprises CdZn(S)Se or ZnSeTe.

24. A light emitting device comprising a light emitting diode emitting light having the first photon energy and attached to the semiconductor construction of claim 19.

25. The semiconductor construction of claim 24, wherein the re-emitting semiconductor construction further comprises an absorbing layer closely adjacent to the potential well and having a band gap energy greater than the potential well transition energy and smaller than the first photon energy.

26. The semiconductor construction of claim 24, wherein the re-emitting semiconductor construction further comprises a first window construction having a band gap energy greater than the first photon energy.

27. The semiconductor construction of claim 24, wherein the re-emitting semiconductor construction further comprises a first strain-compensation layer compensating for a strain in the II-VI potential well.

28. A semiconductor construction comprising:
a substrate comprising Ge capable of being etched by a first etchant;
an etch-stop construction monolithically grown on the substrate and comprising (Al)GaInAs, (Al)GaAs, AlInP, GaInP, or Al(Ga)AsP, the etch-stop construction being capable of withstanding the first etchant;
a re-emitting semiconductor construction monolithically grown on the etch-stop construction and capable of converting at least a portion of light having a first photon energy to light having a second photon energy smaller than the first photon energy, the re-emitting semiconductor construction comprising:
a II-VI semiconductor potential well having a band gap energy smaller than the first photon energy and a potential well transition energy substantially equal to the second photon energy; and
an absorbing layer closely adjacent to the potential well and having a band gap energy greater than the potential well transition energy and smaller than the first photon energy.

29. The semiconductor construction of claim 28, wherein the re-emitting semiconductor construction further comprises a first window construction having a band gap energy greater than the first photon energy.

30. The semiconductor construction of claim 29 further comprising a light emitting diode (LED) emitting light having the first photon energy, the LED being attached to the re-emitting semiconductor construction, the window being disposed between the absorbing layer and the LED.

31. The semiconductor construction of claim 28, wherein the first photon energy corresponds to a blue or UV light.

32. The semiconductor construction of claim 28, wherein the potential well comprises CdZn(S)Se or ZnSeTe.

33. A semiconductor construction comprising:
a semiconductor substrate capable of withstanding a first etchant;
a semiconductor sacrificial layer monolithically grown on the substrate and capable of being etched by the first etchant;
a re-emitting semiconductor construction monolithically grown on the sacrificial layer and capable of converting at least a portion of light having a first photon energy to light having a second photon energy smaller than the first photon energy, the re-emitting semiconductor construction comprising:
a II-VI semiconductor potential well having a band gap energy smaller than the first photon energy and a potential well transition energy substantially equal to the second photon energy; and
an absorbing layer closely adjacent to the potential well and having a band gap energy greater than the potential well transition energy and smaller than the first photon energy;
wherein, at least some layers in the re-emitting semiconductor construction can withstand the first etchant.

34. The semiconductor construction of claim 33, wherein the re-emitting semiconductor construction further comprises a first window construction having a band gap energy greater than the first photon energy.

35. The semiconductor construction of claim 34 further comprising a light emitting diode (LED) emitting light having the first photon energy, the LED being attached to the re-emitting semiconductor construction, the window being disposed between the absorbing layer and the LED.

36. The semiconductor construction of claim 33, wherein the substrate comprises at least one of Ge and GaAs.

37. The semiconductor construction of claim 33, wherein the sacrificial layer comprises at least one of Al, Mg, AlAs and Mg(Zn)Se.

38. The semiconductor construction of claim 33, wherein the sacrificial layer is grown pseudomorphic on the substrate.

39. The semiconductor construction of claim 33, wherein the sacrificial layer is lattice matched to the substrate.

40. The semiconductor construction of claim 33, wherein the first photon energy corresponds to a blue or UV light.

41. The semiconductor construction of claim 33, wherein the potential well comprises Cd(Mg)ZnSe, CdZn(S)Se, or ZnSeTe.

42. The semiconductor construction of claim 33, wherein the re-emitting semiconductor construction can withstand the first etchant.

43. A semiconductor system, comprising:
a plurality of discrete light sources monolithically integrated onto a first substrate; and
a semiconductor construction comprising:
a second substrate capable of being etched by a first etchant;
an etch-stop construction monolithically grown on the second substrate and capable of withstanding the first etchant; and
a re-emitting semiconductor construction monolithically grown on the etch-stop construction and capable of converting at least a portion of light emitted by each of the plurality of discrete light source to a longer wavelength light;
wherein the re-emitting semiconductor construction is attached to and covers the plurality of discrete light sources.

44. The semiconductor system of claim 43, wherein each discrete light source is a III-V LED.

45. The semiconductor system of claim 43, wherein the second substrate comprises one of InP, GaAs, and Ge.

46. The semiconductor system of claim 43, wherein the etch-stop construction comprises one of AlGaInAs, GaInAsP, AlGaAs, GaInP, AlInP, GaInAs, AlInAs, GaAs, and BeTe.

47. The semiconductor system of claim 43, wherein the re-emitting semiconductor construction comprises a II-VI potential well.

48. A method of fabricating a semiconductor construction, comprising the steps of:
(a) providing a substrate;
(b) monolithically growing an etch-stop layer on the substrate;
(c) monolithically growing a potential well on the etch-stop layer;
(d) bonding the potential well to a light source;
(e) removing the substrate by a first etchant that the etch-stop layer can withstand; and
(f) removing the etch-stop layer by a second etchant.

49. The method of claim 48, wherein steps (a) through (f) are carried out sequentially.

50. The method of claim 48, wherein the potential well is capable of converting at least a portion of light that is emitted by the light source to a longer wavelength light.

51. The method of claim 48 further comprising the step of monolithically growing an absorbing layer closely adjacent to and having a band gap energy greater than a transition energy of the potential well.

52. The method of claim 48 further comprising the step of monolithically growing a window construction having a band gap energy greater than an energy of a photon emitted by the light source.
